(19) United States
(12) Patent Application Publication
(10) Pub. No.: US 2022/0262665 A1
(43) Pub. Date: Aug. 18, 2022

(54) ELEMENT TRANSFER DEVICE AND ELEMENT TRANSFER METHOD

(71) Applicant: Japan Display Inc., Tokyo (JP)

(72) Inventor: Hideaki ABE, Tokyo (JP)

(73) Assignee: Japan Display Inc., Tokyo (JP)

(21) Appl. No.: 17/668,398

(22) Filed: Feb. 10, 2022

Related U.S. Application Data
(63) Continuation of application No. PCT/JP2020/023800, filed on Jun. 17, 2020.

(30) Foreign Application Priority Data
Aug. 14, 2019 (JP) 2019-148881

(51) Int. Cl. H01L 21/683; H01L 23/00

(52) U.S. Cl. CPC H01L 21/6835; H01L 24/95; H01L 2224/29339; H01L 2224/95001; H01L 2224/2929; H01L 24/29

(57) ABSTRACT

An element transfer device includes an elastic sheet including a through hole and a pickup portion including a shaft portion, a first head portion at a first end of the shaft portion, and a second head portion at a second end of the shaft portion. The first head portion includes a pickup surface for adhering an element. The shaft portion is inserted into the through hole. The first head portion and the second head portion sandwich the elastic sheet. An outer diameter of the first head portion and an outer diameter of the second head portion are larger than an opening diameter of the through hole.

### CROSS-REFERENCE TO RELATED APPLICATIONS

This application is a Continuation of International Patent Application No. PCT/JP2020/023800, filed on Jun. 17, 2020, which claims priority to Japanese Patent Application No. 2019-148881, filed on Aug. 14, 2019, the entire contents of each are incorporated herein by its reference.

### BACKGROUND OF THE INVENTION

### Field

One embodiment of the present invention relates to an element transfer device that picks up an element from an element substrate on which the element is formed and transfers the element to a circuit substrate on which a circuit for driving the element is formed.

### Description of the Related Art

In a small or medium-sized display device such as a smart phone, a display using liquid crystals or OLEDs (Organic Light Emitting Diodes) has been commercialized. In particular, an OLED display device using the OLEDs which are self-light emitting elements has the advantages of high-contrast and does not require a backlight, as compared with a liquid crystal display device. However, since the OLEDs are composed of organic compounds, it is difficult to secure high reliability of the OLED display device due to deterioration of the organic compounds.

On the other hand, a so-called micro LED display in which minute micro LEDs are placed in pixels arranged in a matrix has been developed as a next-generation display. The micro LEDs are self-emitting elements similar to the OLEDs, but unlike OLEDs, the micro LEDs are composed of inorganic compounds containing gallium (Ga) or indium (In). Therefore, it is easier to ensure a highly reliable micro LED display as compared with the OLED display. In addition, micro LEDs have high light emission efficiency and high brightness. Therefore, the micro LED display is expected to be the next generation display with high reliability, high brightness, and high contrast.

The micro LEDs are formed on a substrate such as sapphire similar to typical LEDs, and are separated into individual micro LEDs by dicing the substrate. In the micro LED display, it is necessary to place the diced micro LEDs in the pixels of a circuit substrate (also referred to as a backplane or a TFT substrate). As one of the methods for placing the micro LEDs on the circuit substrate, a transfer substrate is used to pick up a plurality of micro LEDs from an element substrate, the transfer substrate is attached to the circuit substrate, and the plurality of micro LEDs are transferred to the circuit substrate (See, for example, U.S. Patent Application Publication No. 2016/0240516 or U.S. Patent Application Publication No. 2017/0047306).

### BRIEF SUMMARY OF THE INVENTION

An element transfer device according to an embodiment of the present invention includes an elastic sheet including a through hole and a pickup portion including a shaft portion, a first head portion at a first end of the shaft portion, and a second head portion at a second end of the shaft portion. The first head portion includes a pickup surface for adhering an element. The shaft portion is inserted into the through hole. The first head portion and the second head portion sandwich the elastic sheet. An outer diameter of the first head portion and an outer diameter of the second head portion are larger than an opening diameter of the through hole.

A method for transferring an element according to an embodiment of the present invention includes the steps of stretching or shrinking an elastic sheet of an element transfer device so that a distance between pickup portions of the element transfer device corresponds to a distance between elements over a first substrate, adhering the elements to pickup surfaces of the pickup portions, releasing the elements from the first substrate, stretching or shrinking the elastic sheet of the element transfer device so that the distance between the pickup portions of the element transfer device corresponds to a distance between electrodes over a second substrate, placing the elements adhered to the pickup surfaces of the pickup portions on the electrodes, and releasing the elements from the pickup surfaces of the pickup portions.

### BRIEF DESCRIPTION OF THE DRAWINGS

FIG. 1A is a schematic top view of an element transfer device according to an embodiment of the present invention;

FIG. 1B is a schematic top view of an elastic sheet of an element transfer device according to an embodiment of the present invention;

FIG. 1C is a schematic cross-sectional view of an element transfer device according to an embodiment of the present invention;

FIG. 1D is a schematic cross-sectional view of an element transfer device according to an embodiment of the present invention when an elastic sheet is stretched;

FIG. 2A is a schematic top view of an element transfer device according to an embodiment of the present invention;

FIG. 2B is a schematic cross-sectional view of an element transfer device according to an embodiment of the present invention;

FIG. 2C is a schematic cross-sectional view of an element transfer device according to an embodiment of the present invention;

FIG. 2D is a schematic cross-sectional view of an element transfer device according to an embodiment of the present invention;

FIG. 3A is a schematic cross-sectional view of an element transfer device according to an embodiment of the present invention;

FIG. 3B is a schematic cross-sectional view of the element transfer device according to an embodiment of the present invention when an elastic sheet is stretched;

FIG. 4A is a schematic cross-sectional view of an element transfer device according to an embodiment of the present invention;

FIG. 4B is a schematic cross-sectional view of the element transfer device according to an embodiment of the present invention when an elastic sheet is stretched;

FIG. 5A is a schematic top view of an element transfer device according to an embodiment of the present invention;

FIG. 5B is a schematic cross-sectional view of an element transfer device according to an embodiment of the present invention;

FIG. 5C is a schematic cross-sectional view of an element transfer device according to an embodiment of the present invention;

FIG. 6A is a schematic cross-sectional view of an element transfer device according to an embodiment of the present invention;

FIG. 6B is a schematic cross-sectional view of an element transfer device according to an embodiment of the present invention;

FIG. 6C is a schematic diagram of a structure of an intersection of a first wire and a second wire of an element transfer device according to an embodiment of the present invention;

FIG. 7A is a schematic top view of an element transfer device according to an embodiment of the present invention;

FIG. 7B is a schematic cross-sectional view of an element transfer device according to an embodiment of the present invention;

FIG. 7C is a schematic enlarged cross-sectional view of an element transfer device according to an embodiment of the present invention;

FIG. 8 is a schematic top view of an element transfer device according to an embodiment of the present invention;

FIG. 9 is a schematic perspective view of an element substrate used in an element transfer method according to the embodiment of the present invention;

FIG. 10 is a block diagram showing a layout configuration of a circuit substrate used in an element transfer method according to an embodiment of the present invention;

FIG. 11 is a flowchart of an element transfer method according to an embodiment of the present invention;

FIG. 12A is a schematic cross-sectional view showing an element transfer method according to an embodiment of the present invention;

FIG. 12B is a schematic cross-sectional view showing an element transfer method according to an embodiment of the present invention;

FIG. 12C is a schematic cross-sectional view showing an element transfer method according to an embodiment of the present invention;

FIG. 12D is a schematic cross-sectional view showing an element transfer method according to an embodiment of the present invention;

FIG. 12E is a schematic cross-sectional view showing an element transfer method according to an embodiment of the present invention;

FIG. 12F is a schematic cross-sectional view showing an element transfer method according to an embodiment of the present invention;

FIG. 12G is a schematic cross-sectional view showing an element transfer method according to an embodiment of the present invention; and

FIG. 12H is a schematic cross-sectional view showing an element transfer method according to an embodiment of the present invention.

### DESCRIPTION OF EMBODIMENTS

If a distance between the elements arranged on the element substrate and a distance between the elements transferred to the circuit substrate are different, it is not possible to transfer a plurality of micro LEDs, and the only method is to transfer them one by one. In this case, not only the number of repetitions of the transfer process increases, but also the manufacturing tact time increases significantly, which are factors in increasing the manufacturing cost of the device.

In view of the above problems, it is one object of an embodiment of the present invention to provide an element transfer device which can transfer elements to a circuit substrate at a distance different from a distance between elements arranged on an element substrate. Further, it is one object of an embodiment of the present invention to provide an element transfer method for transferring the elements to a circuit substrate at a distance different from a distance between elements arranged on the element substrate.

Hereinafter, embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In each embodiment of the present invention, although the term “over” or “below” is used for convenience of explanation, the vertical relationship in the explanation may be reversed. For example, the expression “element over a substrate” merely explains the vertical relationship between the substrate and the element, and another member may be placed between the substrate and the element.

In the present specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the present specification, an element is, for example, a microelectromechanical system (MEMS), a laser diode (LD), a mini LED, or a micro LED, or the like, but is not limited thereto.

### First Embodiment

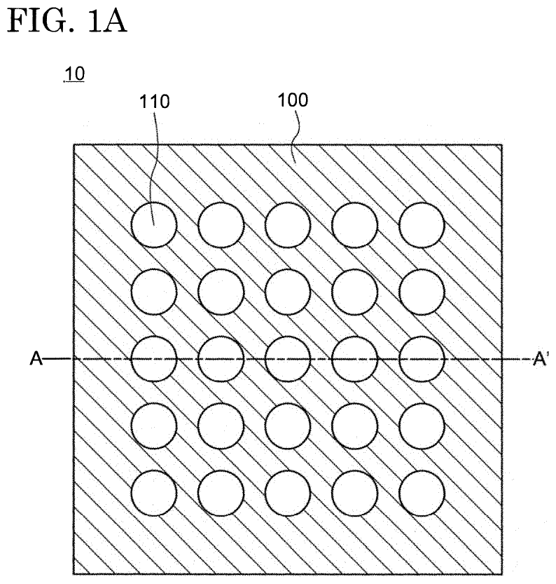

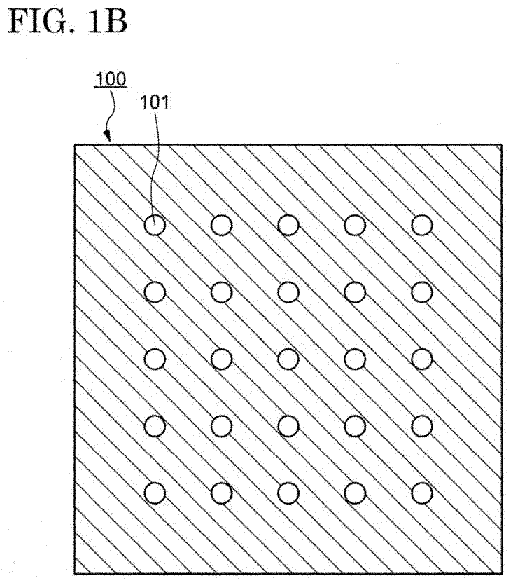

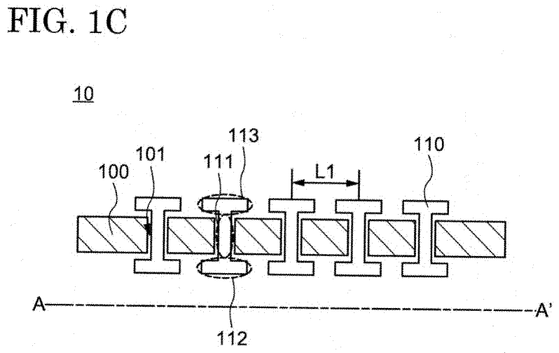

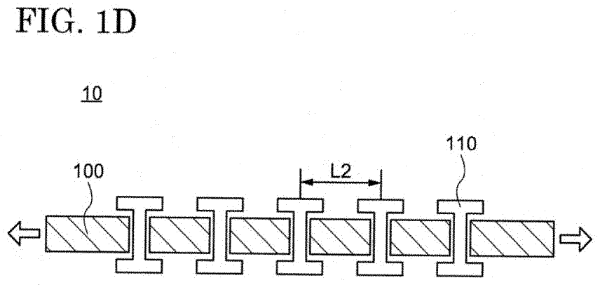

An element transfer device 10 according to an embodiment of the present invention is described with reference to FIGS. 1A to 1D.

### [Structure]

FIG. 1A is a schematic top view of the element transfer device 10 according to the embodiment of the present invention. As shown in FIG. 1A, the element transfer device 10 includes an elastic sheet 100 and a plurality of pickup portions 110.

FIG. 1B is a schematic top view of the elastic sheet 100 of the element transfer device 10 according to the embodiment of the present invention. The pickup portion 110 of the elastic sheet 100 shown in FIG. 1B is not described in order to facilitate understanding of the element transfer device 10. As shown in FIG. 1B, the elastic sheet 100 is provided with a through hole 101. The position of the pickup portion 110 shown in FIG. 1A coincides with the position of the through hole 101 shown in FIG. 1 B. That is, the pickup portion 110 is fitted in the through hole 101 of the elastic sheet 100.

FIG. 1C is a schematic cross-sectional view of the element transfer device 10 according to the embodiment of the present invention. Specifically, FIG. 1C is a schematic cross-sectional view cut along the line A-A′ of FIG. 1A. As shown in FIG. 1C, the pickup portion 110 includes a shaft portion 111, a first head portion 112, and a second head portion 113. The first head portion 112 is provided at the first end of the shaft portion 111, and the second head portion 113 is provided at the second end opposite to the first end of the shaft portion 111. Further, the outer diameter of each of the first head portion 112 and the second head portion 113 is larger than the outer diameter of the shaft portion 111. In the pickup portion 110, the first head portion 112 and the second head portion 113 sandwich the elastic sheet 100, and the shaft portion 111 is inserted into the through hole 101.

The outer diameter of the shaft portion 111 is smaller than the opening diameter of the through hole 101. Further, the length of the shaft portion 111 is larger than the depth of the through hole 101 (corresponding to the film thickness of the elastic sheet 100). Therefore, the shaft portion 111 is movable in the through hole 101 not only in the in-plane direction of the elastic sheet 100 but also in the film thickness direction.

Further, by making the outer diameter of the shaft portion 111 substantially match the opening diameter of the through hole 101, it is also possible to configure the shaft portion 111 so that it hardly moves in the in-plane direction of the elastic sheet 100. Furthermore, by making the length of the shaft portion 111 substantially match the depth of the through hole 101, it is also possible to configure the shaft portion 111 so that it hardly moves in the film thickness direction of the elastic sheet 100.

On the other hand, each of the first head portion 112 and the second head portion 113 is located outside the through hole 101 and protrudes from the opening surface of the through hole 101. Further, the outer diameters of the first head portion 112 and the second head portion 113 are larger than the opening diameter of the through hole 101. Therefore, the first head portion 112 and the second head portion 113 do not enter the through hole 101. Therefore, the first head portion 112 and the second head portion 113 have a function as fasteners for preventing the pickup portion 110 from being pulled out of the through hole 101 of the elastic sheet 100.

The outer diameters of the shaft portion 111, the first head portion 112, and the second head portion 113 can be appropriately determined in consideration of the size or shape of the element. For example, the outer diameter of the first head portion 112 or the second head portion 113 can be greater than or equal to 1.25 times and less than or equal to 5 times with respect to the outer diameter of the shaft portion 111. The outer diameter of the first head portion 112 and the outer diameter of the second head portion 113 may be different.

The length of the shaft portion 111 may be greater than or equal to the film thickness of the elastic sheet 100. When the length of the shaft portion 111 is larger than the film thickness of the elastic sheet 100, the moving range of the shaft portion 111 in the film thickness direction of the elastic sheet 100 becomes large. However, if the length of the shaft portion 111 is too large compared to the film thickness of the elastic sheet 100, the first head portion 112 or the second head portion 113 is too far from the elastic sheet 100, so that the positioning arrangement of the pickup portion 110 and the element becomes unstable. Therefore, the length of the shaft portion 111 is preferably greater than or equal to 1 and less than or equal to 2 times with respect to the film thickness of the elastic sheet 100.

At least one of the first head portion 112 and the second head portion 113 includes a flat surface on its surface. The flat surface has a function of adhering and picking up the element. In the following description, the flat surface in contact with the element is referred to as a pickup surface, and unless otherwise specified, the pickup surface is formed on the surface of the first head portion 112. It is preferable that the surface of the other of the first head portion 112 and the second head portion 113 also has a flat surface. In this case, since pressure can be applied evenly on the surface from the opposite side of the pickup surface, it is easy to adjust the parallelism of the pickup surface.

Although the cross-sectional shapes of the through holes 101, the shaft portion 111, the first head portion 112, and the second head portion 113 shown in FIGS. 1A to 1C are circular, they are not limited to this shape. The cross-sectional shape of each of the through hole 101, the shaft portion 111, the first head portion 112, and the second head portion 113 may be polygonal or elliptical. That is, each of the through hole 101, the shaft portion 111, the first head portion 112, and the second head portion 113 can have various shapes such as a polygonal pillar, a cylinder, or an elliptical pillar.

Similarly, the shape of the flat surface of the first head portion 112 or the second head portion 113 may be not only circular but also polygonal or elliptical. In particular, the surface roughness of the pickup surface is less than or equal to 1 μm, preferably less than or equal to 0.5 μm. When the surface roughness of the pickup surface is small, the area in contact with the element increases, so that the adhesive force between the pickup surface and the element can be increased.

The size of the elastic sheet 100 can be decided as appropriate in consideration of the substrate on which the element is formed (hereinafter referred to as “first substrate” or “element substrate”) or the substrate on which the circuit is formed (hereinafter referred to as “second substrate” or “circuit substrate”). Although the size of the elastic sheet 100 is, for example, 50 mm square, the size is not limited to this. Further, for example, although the shape of the elastic sheet 100 is rectangular, the shape is not limited to this. The shape of the elastic sheet 100 can also be polygonal, circular, or elliptical.

The film thickness of the elastic sheet 100 can be appropriately determined in consideration of the rigidity of the element transfer device 10. Although the film thickness of the elastic sheet 100 is, for example, greater than or equal to 1 mm and less than or equal to 10 mm, the film thickness is not limited to this. When the film thickness of the elastic sheet 100 is thin, the rigidity of the element transfer device 10 becomes weak. Further, when the elastic sheet 100 has a thick film thickness, the elasticity of the elastic sheet 100 decreases. Therefore, the film thickness of the elastic sheet 100 is preferably within the above range, which is the thickness at which the through hole 101 is provided.

The number of pickup portions 110 and the distance between the pickup portions 110 can be appropriately determined in consideration of the arrangement of each element on the element substrate or the circuit substrate, the size of the element, or the like. For example, the pickup portions 110 can be arranged in a matrix or a zigzag pattern in the elastic sheet 100.

### [Material]

FIG. 1D is a schematic cross-sectional view of the element transfer device 10 according to the embodiment of the present invention when the elastic sheet 100 is stretched. As shown in FIG. 1D, in the element transfer device 10 the elastic sheet 100 is stretched by applying a force in the in-plane direction of the elastic sheet 100. At the same time, the distance between the pickup portions 110 also extends from L1 in the steady state shown in FIGS. 1C to L2 in the extended state shown in FIG. 1D. The elastic sheet 100 can also be reduced. Therefore, by adjusting the force applied to the elastic sheet 100, the distance between the pickup portions 110 can be adjusted.

The elastic sheet 100 is preferably an elastic material having a deforming property when a force is applied and returning property to the original state when the force is removed. For example, natural rubber (NR), silicone rubber (SI), polyurethane rubber (PUR), fluororubber (FPM), nitrile rubber (NBR), styrene-butadiene rubber (SBR), and butadiene rubber. (BR), isoprene rubber (IR), ethylene propylene diene rubber (EPDM), acrylic rubber (ACM), or isobutyene isoprene rubber (IIR) can be used as a material of the elastic sheet 100. These rubbers are used alone or in combination. In particular, when high heat resistance is required, the material of the elastic sheet 100 is preferably silicone rubber or fluororubber. In addition, the silicone rubber in the present specification includes polydimethylsiloxane (PDMS).

Further, the elastic sheet 100 may contain additives such as a vulcanizing material, a filler, a softener, a coloring agent, or an anti-deterioration agent. Sulfur, a sulfur compound, a peroxide, or the like can be used as the vulcanizing material. Barium sulfate, calcium carbonate, silicic acid, magnesium silicate, calcium silicate, or the like can be used as the filler. Paraffin-based process oil, naphthenic process oil, or the like can be used as the softener. Carbon black, titanium white, ultramarine blue, phthalocyanine, red iron oxide, lead chromate, or the like can be used as the coloring agent. Phenol, wax, or the like can be used as the anti-deterioration agent.

Further, the elastic body 200 may contain a vulcanization aid or a vulcanization accelerator. Zinc stearate, stearate, zinc white, zinc oxide, magnesium oxide, or the like can be used as the vulcanization aid. Thiazoles, thiraums, sulfenamides, dithiocarbamate, or the like may be used as the vulcanization accelerator.

It is preferable that the pickup portion 110 can absorb the repulsive force from the element when the element is picked up or released. Therefore, the same elastic material as the elastic sheet 100 can be used for the pickup portion 110.

Further, in the pickup portion 110, the shaft portion 111, the first head portion 112, or the second head portion 113 may be made of different materials. For example, the shaft portion 111 can be made of a material (a rigid material) having higher rigidity than the first head portion 112 and the second head portion 113. Quartz, glass, silicon or the like can be used as such a rigid material.

On the other hand, a material (a flattening material) that easily forms a flat surface can be used for the first head portion 112 including the pickup surface. a polyimide resin, an acrylic resin, an epoxy resin, a siloxane resin, or the like can be used as such a flattening material. The first head portion 112 can be manufactured by molding a flattening material and adhering it to the shaft portion 111. Further, it can also be manufactured by processing a base material of the first head portion 112 with a rigid material or an elastic material and then applying a flattening material to the surface. That is, the first head portion 112 can have a stacked structure of an elastic material or a rigid material and a flattening material.

### [Modifications]

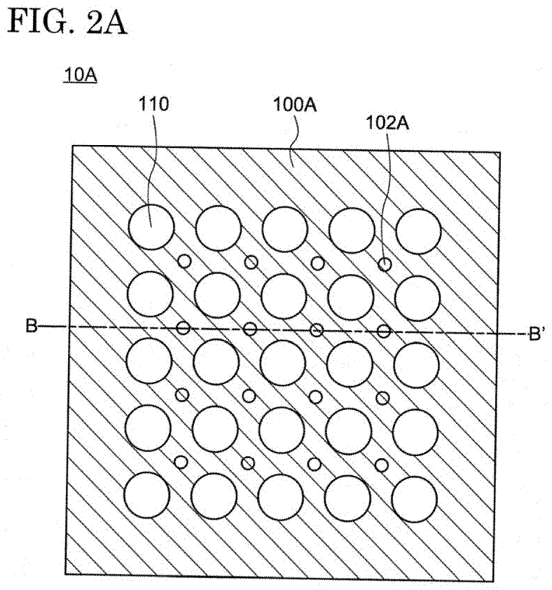

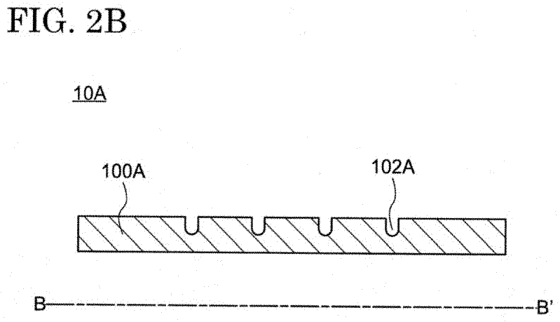

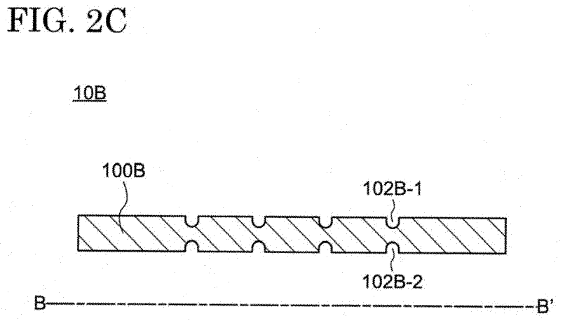

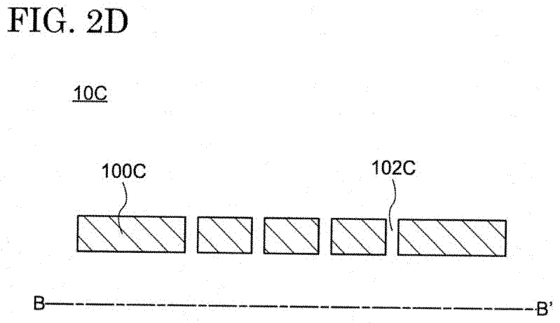

Modifications of the element transfer device 10 according to the embodiment of the present invention are described with reference to FIGS. 2A to 2D.

FIG. 2A is a schematic top view of an element transfer device 10A according to the embodiment of the present invention. Further, FIG. 2B is a schematic cross-sectional view of the element transfer device 10A according to the embodiment of the present invention. Specifically, FIG. 2B is a schematic cross-sectional view cut along the line B-B′ of FIG. 2A. As shown in FIGS. 2A and 2B, the element transfer device 10A includes an elastic sheet 100A, a plurality of recessed portions 102A, and the plurality of pickup portions 110. In the following description, the description of the configuration similar to that of the element transfer device 10 is omitted, and the configuration different from that of the element transfer device 10 is mainly described.

The plurality of recessed portions 102A are provided in a matrix between the pickup portions 110 of the elastic sheet 100A, but is not limited to this. When the recessed portions 102A are too large or the number of recessed portions 102A is too large, the rigidity of the elastic sheet 100A is decreased. Therefore, the size, number, or position of the recessed portions 102A can be appropriately determined in consideration of the rigidity of the elastic sheet 100A.

Although the cross-sectional shape of the recessed portion 102A shown in FIGS. 2A and 2B is circular, the shape is not limited to circular. The cross-sectional shape of the recessed portion 102A may be polygonal or elliptical. Further, the recessed portion 102A may be provided similar to a groove extended in one direction or a plurality of directions.

FIG. 2C is a schematic cross-sectional view of an element transfer device 10B according to the embodiment of the present invention. The element transfer device 10B includes an elastic sheet 100B, a plurality of first recessed portions 102B-1, a plurality of second recessed portions 102B-2, and the pickup portion 110 (not shown in FIG. 2C). The first recessed portion 102B-1 is provided on one surface of the elastic sheet 100B, and the second recessed portion 102B-2 is provided on the other surface located on the opposite side of the elastic sheet 100B. In the element transfer device 10B shown in FIG. 2C, although the first recessed portion 102B-1 and the second recessed portion 102B-2 are provided at positions which match each other, the positions of the first recessed portion 102B-1 and the second recessed portion 102B-2 do not have to match.

FIG. 2D is a schematic cross-sectional view of an element transfer device 10C according to the embodiment of the present invention. The element transfer device 10C includes an elastic sheet 100C, a plurality of through holes 102C, and the plurality of pickup portions 110 (not shown in FIG. 2D). The plurality of through holes 102C are provided between the pickup portions 110.

In the portion of the elastic sheet 100A provided with the recessed portion 102A, the portion of the elastic sheet 1006 provided with the first recessed portion 102B-1 and the second recessed portion 102B-2, and the portion provided with the through hole 102C of the elastic sheet 100C, the rigidity is decreased but the elasticity is improved. Therefore, the distance between the pickup portions 110 of the elastic sheets 100A to 100C of the element transfer devices 10A to 10C can be further extended.

In the element transfer device 10 or the modifications thereof according to the present embodiment, the pickup portion 110 is fitted in the through hole 101 provided in the elastic sheet 100. Therefore, when the elastic sheet 100 is stretched or shrunk, the distance between the pickup portions 110 is also extended and shrunk. Therefore, when picking up or releasing the element, the distance between the pickup portions 110 can be adjusted according to the distance between the elements arranged on the element substrate or the distance between the electrodes formed on the circuit substrate. Further, since the number of times the action of pickup or release is repeated can be reduced, defects in the element transfer process are suppressed, and the yield is improved.

The above configuration is merely one embodiment including modifications, and the present invention is not limited to the above configuration.

### Second Embodiment

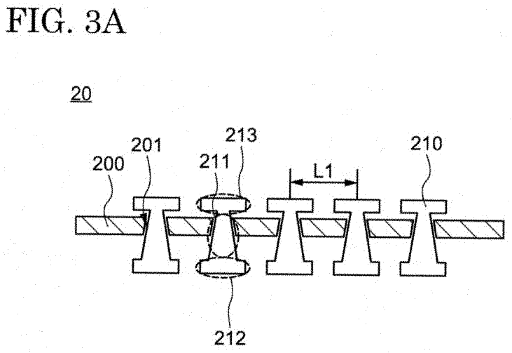

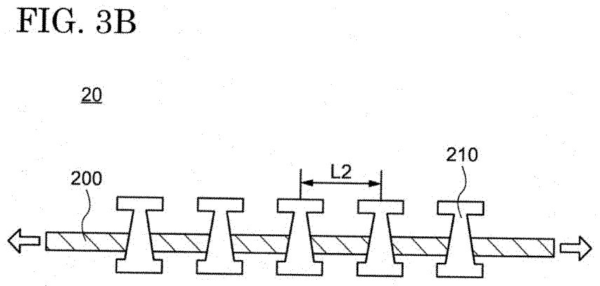

An element transfer device 20 according to an embodiment of the present invention is described with reference to FIGS. 3A and 3B. In the following description, the description of the configuration similar to that of the first embodiment is omitted, and the configuration different from that of the first embodiment is mainly described.

FIG. 3A is a schematic cross-sectional view of the element transfer device 20 according to the embodiment of the present invention. As shown in FIG. 3A, the element transfer device 20 includes an elastic sheet 200 and a plurality of pickup portions 210. Further, the pickup portion 210 is fitted in the through hole 201 of the elastic sheet 200. In the steady state, the distance between two adjacent pickup portions on the elastic sheet 200 is L1.

The pickup portion 210 includes a shaft portion 211, a first head portion 212, and a second head portion 213. A first head portion 212 is provided at one end of the shaft portion 211, and a second head portion 213 is provided at the other end of the shaft portion 211.

The shaft portion 211 has a taper, and the outer diameter differs depending on the position. That is, the outer diameter of the shaft portion 211 is at its maximum on the first head portion 212 side and at its minimum on the second head portion 213 side. The outer diameter of the first head portion 212 is larger than the maximum outer diameter of the shaft portion 211. Further, the outer diameter of the second head portion 213 is larger than the minimum outer diameter of the shaft portion 211.

The through hole 201 also has the same taper as the shaft portion 211, and the opening diameter differs depending on the position. That is, the opening diameter of the through hole 201 is at its maximum on the first opening surface located on the first head portion 212 side and is at its minimum on the second head portion 213 side. The outer diameter of the first head portion 212 is larger than the opening diameter of the first opening surface. Further, the outer diameter of the second head portion 213 is larger than the opening diameter of the second opening surface.

The opening diameter of the first opening surface or the opening diameter of the second opening surface of the through hole 201 is preferably smaller than the maximum outer diameter of the shaft portion 211, but not limited to this.

The taper angles of the shaft portion 211 and the through hole 201 can be appropriately determined in consideration of the length of the shaft portion 211, the film thickness of the elastic sheet 200, and the like. Further, although it is preferable that the taper angle of the shaft portion 211 and the taper angle of the through hole 201 are the same, the taper angle is not limited to this.

FIG. 3B is a schematic cross-sectional view of the element transfer device 20 according to the embodiment of the present invention when the elastic sheet 200 is stretched. As shown in FIG. 3B, in the element transfer device 20, the elastic sheet 200 is stretched by applying a force in the in-plane direction of the elastic sheet 200. At the same time, the distance between the pickup portions 210 also extends from L1 in the steady state shown in FIG. 3A to L2 in the extended state shown in FIG. 3B. Therefore, by adjusting the force applied to the elastic sheet 200, the distance between the pickup portions 210 can be adjusted.

When the opening diameter of the first opening surface or the opening diameter of the second opening surface of the through hole 201 is smaller than the maximum outer diameter of the shaft portion 211, the shaft portion 211 can be fixed at a predetermined position as shown in FIG. 3B. Therefore, since the pickup portion 210 can be fixed to the elastic sheet 200 in the stretched state, the element transfer device 20 can be used to stably pick up or release the element.

### [Modification]

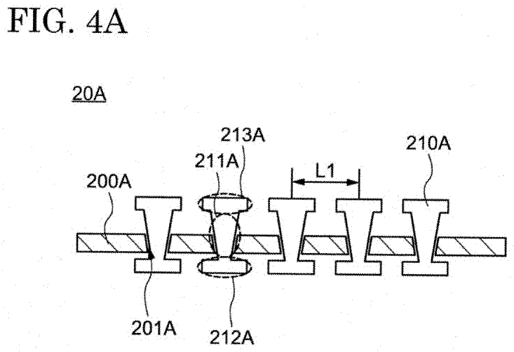

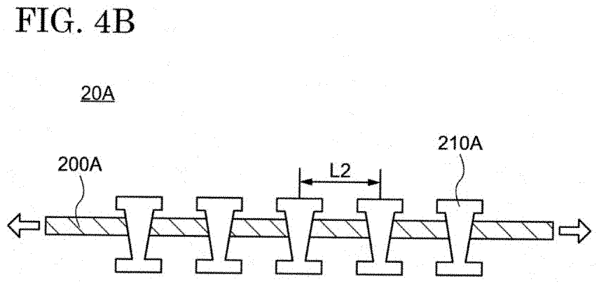

A modification of the element transfer device 20 according to the present embodiment is described with reference to FIGS. 4A and 4B.

FIG. 4A is a schematic cross-sectional view of an element transfer device 20A according to the embodiment of the present invention. As shown in FIG. 4A, the element transfer device 20A includes an elastic sheet 200A and a plurality of pickup portions 210A. Further, the pickup portion 210A is fitted in the through hole 201A of the elastic sheet 200A. In the steady state, the distance between two adjacent pickup portions 210A on the elastic sheet 200 is L1. In the following description, the description of the configuration similar to that of the element transfer device 20 is omitted, and the configuration different from that of the element transfer device 20 is mainly described.

The pickup portion 210A includes a shaft portion 211A, a first head portion 212A, and a second head portion 213A. A first head portion 212A is provided at one end of the shaft portion 211A, and a second head portion 213A is provided at the other end of the shaft portion 211A.

The shaft portion 211A has a taper, and the outer diameter differs depending on the position. That is, the outer diameter of the shaft portion 211A is at its minimum on the first head portion 212A side and is at its maximum on the second head portion 213A side. The outer diameter of the first head portion 212A is larger than the minimum outer diameter of the shaft portion 211A. Further, the outer diameter of the second head portion 213A is larger than the maximum outer diameter of the shaft portion 211A.

The through hole 201A also has the same taper as the shaft portion 211A, and the opening diameter differs depending on the position. That is, the opening diameter of the through hole 201A is at its minimum on the first opening surface located on the first head portion 212A side and is at its maximum on the second head portion 213A side. The outer diameter of the first head portion 212A is larger than the opening diameter of the first opening surface. Further, the outer diameter of the second head portion 213A is larger than the opening diameter of the second opening surface.

FIG. 4B is a schematic cross-sectional view of the element transfer device 20A according to the embodiment of the present invention when the elastic sheet 200A is stretched. As shown in FIG. 4B, in the element transfer device 20A, the elastic sheet 200A is stretched by applying a force in the in-plane direction of the elastic sheet 200A. At the same time, the distance between the pickup portions 210A also extends from L1 in the steady state shown in FIG. 4A to L2 in the extended state shown in FIG. 4B. Therefore, by adjusting the force applied to the elastic sheet 200A, the distance between the pickup portions 110A can be adjusted.

When the opening diameter of the first opening surface or the opening diameter of the second opening surface of the through hole 201A is smaller than the maximum outer diameter of the shaft portion 211A, the shaft portion 211A can be fixed at a predetermined position as shown in FIG. 4B. Therefore, since the pickup portion 210A can be fixed to the elastic sheet 200A in the stretched state, the element transfer device 20A can be used to stably pick up or release the element.

In the element transfer device 20 or the modification thereof according to the present embodiment, the shaft portion 211 of the pickup portion 210 can be fixed at a predetermined position by utilizing the taper of the through hole 201. Therefore, the position of the pickup portion 210 is stable. Further, since the shaft portion 211 and the through hole 201 have a taper, even when the elastic sheet 200 is stretched and the opening diameter of the through hole 201 is expanded, the shaft portion 211 can be fixed at a predetermined position. Therefore, not only the distance between the pickup portions 210 can be adjusted, but also the position of the pickup portions 210 can be stabilized. Therefore, defects in the element transfer process are suppressed, and the yield is improved.

### Third Embodiment

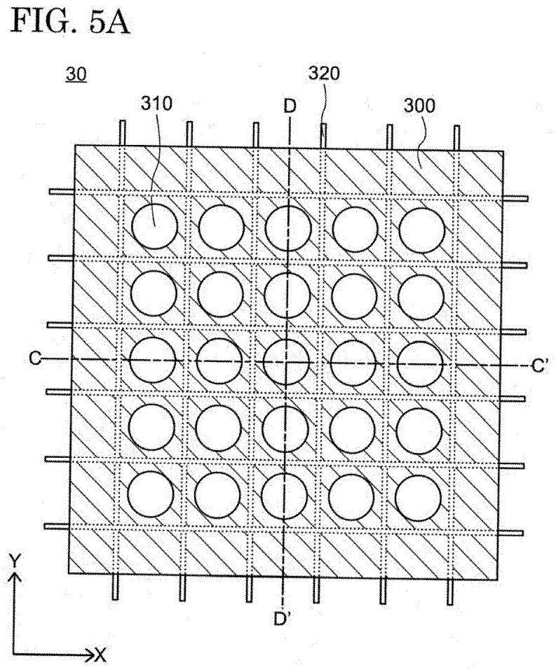

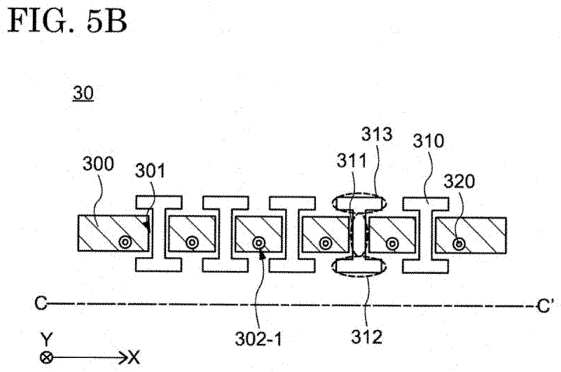

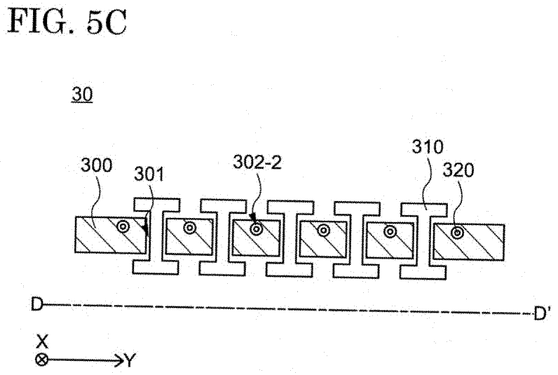

An element transfer device 30 according to an embodiment of the present invention is described with reference to FIGS. 5A to 5C. In the following description, the description of the configuration similar to that of the first embodiment or the second embodiment will be omitted, and the configuration different from that of the first embodiment or the second embodiment is mainly described.

FIG. 5A is a schematic top view of the element transfer device 30 according to the embodiment of the present invention. As shown in FIG. 5A, the element transfer device 30 includes an elastic sheet 300, a plurality of pickup portions 310, and a plurality of wires 320. The wire 320 penetrates the elastic sheet 300 not only in the X direction (first direction) but also in the Y direction (second direction) orthogonal to the X direction.

FIGS. 5B and 5C are schematic cross-sectional views of the element transfer device 30 according to the embodiment of the present invention. Specifically, FIG. 5B is a schematic cross-sectional view cut along the line C-C′ of FIG. 5A, and FIG. 5C is a schematic cross-sectional view cut along the line D-D′ of FIG. 5A.

The elastic sheet 300 is provided with a through hole 301, a first hollow pipe 302-1, and a second hollow tube 302-2. The pickup portion 310 includes a shaft portion 311 and a first head portion 312, and a second head portion 313, and is fitted in the through hole 301. Each of the first hollow tube 302-1 and the second hollow tube 302-2 is provided between the through holes 301. The first hollow tube 302-1 extends in the elastic sheet 300 in the Y direction, and the second hollow tube 302-2 extends in the elastic sheet 300 in the X direction. Further, the first hollow tube 302-1 is provided in a region on the first head portion 312 side of the elastic sheet 300, and the second hollow pipe 302-2 is provided in a region on the second head portion 313 side of the elastic sheet 300. Therefore, the first hollow tube 302-1 and the second hollow tube 302-2 are not connected with each other. Further, the wire 320 is passed through each of the first hollow tube 302-1 and the second hollow tube 302-2. Therefore, the wire 320 is not in contact with the pickup portion 310.

The wire 320 has a function of increasing the rigidity of the element transfer device 30. Therefore, a rigid material is preferable as the material of the wire 320. For example, an aluminum wire, a steel wire, a brass wire, a stainless steel wire, a piano wire, or the like can be used as the material of the wire.

### [Modification]

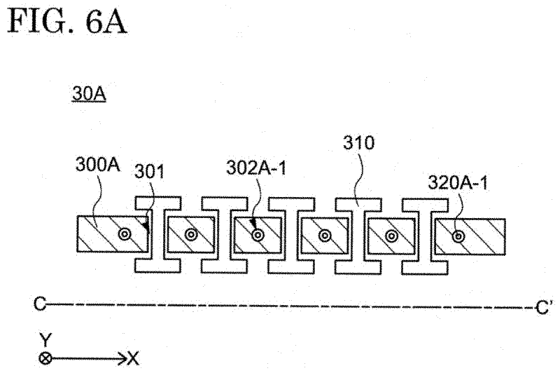

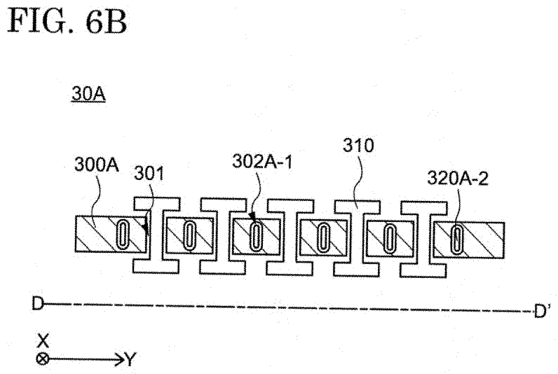

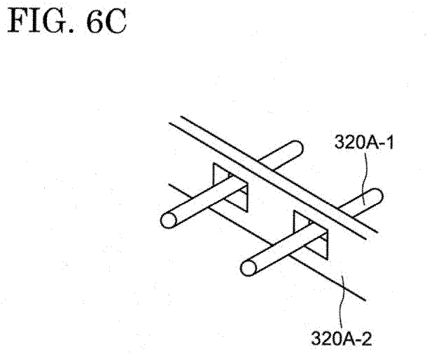

A modification of the element transfer device 30 according to the present embodiment is described with reference to FIGS. 6A to 6C.

FIGS. 6A and 6B are schematic cross-sectional views of an element transfer device 30A according to the embodiment of the present invention. Since the top view of the element transfer device 30A is almost the same as the top view of the element transfer device 30 shown in FIG. 5A, the drawing is omitted here. However, FIG. 5A is referred to for the cutting line in FIGS. 6A and 6B. That is, FIG. 6A is a schematic cross-sectional view cut along the line C-C′ of FIG. 5Awhen corresponding to the element transfer device 30A, and FIG. 6B is a schematic view cross-sectional view cut along the line D-D′ line of 5A when corresponding to the element transfer device 30A.

The element transfer device 30A includes an elastic sheet 300A, a plurality of pickup portions 310, a first wire 320A-1, and a second wire 320A-2. The elastic sheet 300A is provided with a through hole 301, a first hollow tube 302A-1, and a second hollow tube 302A-2.

Each of the first hollow tube 302A-1 and the second hollow tube 302A-2 is provided between the through holes 301A. Further, each of the first hollow tube 302A-1 and the second hollow tube 302A-2 is provided in a central region of the elastic sheet 300A in the film thickness direction. Further, the first hollow tube 302A-1 extends in the elastic sheet 300A in the Y direction, and the second hollow tube 302A-2 extends in the elastic sheet 300A in the X direction. In the elastic sheet 300A, the first hollow tube 302A-1 and the second hollow tube 302A-2 intersect and are connected with each other.

The first wire 320A-1 is passed through the first hollow tube 302A-1. On the other hand, the second wire 320A-2 is passed through the second hollow tube 302A-2. The cross-sectional area of the second hollow tube 302A-2 is larger than the cross-sectional area of the first hollow tube 302A-1. Therefore, the second wire 320A-2 having the cross-sectional area larger than that of the first wire 320A-1 can be passed through the second hollow tube 302A-2.

The cross-sectional shape of the first hollow tube 302A-1 is different from the cross-sectional shape of the second hollow tube 302A-2. In FIGS. 6A and 6B, the cross-sectional shape of the first hollow tube 302A-1 is circular, and the cross-sectional shape of the second hollow tube 302A-2 is a rectangular shape with rounded corners, but the cross-sectional shape is not limited to this. The cross-sectional shape of the first hollow tube 302A-1 may be circular, and the cross-sectional shape of the second hollow tube 302A-2 may be a circular shape larger than the circular shape of the first hollow tube 302A-1. The cross-sectional shapes of the first hollow tube 302A-1 and the second hollow tube 302A-2 can be appropriately determined in consideration of the cross-sectional shapes of the first wire 320A-1 and the second wire 320A-2, respectively.

FIG. 6C is a schematic diagram of a structure of the intersection of the first wire 320A-1 and the second wire 320A-2 of the element transfer device 30A according to the embodiment of the present invention. The second wire 320A-2 is provided with an opening portion 321A. At the intersection, the first wire 320A-1 passes through the opening portion 321A provided in the second wire 320A-2. By providing the opening portion 321A in the second wire 320A-2 in this way, one first wire 320A-1 can penetrate the elastic sheet 300A. The opening diameter of the opening portion 321A can be appropriately determined in consideration of the movement of the first wire 320A-1 when the elastic sheet 300A is stretched and shrunk. Further, the cross-sectional shape of the opening 321A is not limited to a rectangle. The cross-sectional shape of the opening 321A can have various shapes such as a circular shape, an elliptical shape, or a polygonal shape.

In the element transfer device 30 or the modification thereof according to the present embodiment, the pickup portion 310 is fitted in the through hole 301 provided in the elastic sheet 100. Therefore, by stretching and shrinking the elastic sheet 300, the distance between the pickup portions 310 can be adjusted. Further, since the wire is provided in the elastic sheet 300, the rigidity of the elastic sheet 300 is also increased. Therefore, the elastic sheet 300 is stable even when a force is applied to the elastic sheet 300. Therefore, defects in the element transfer process are suppressed, and the yield is improved.

### Fourth Embodiment

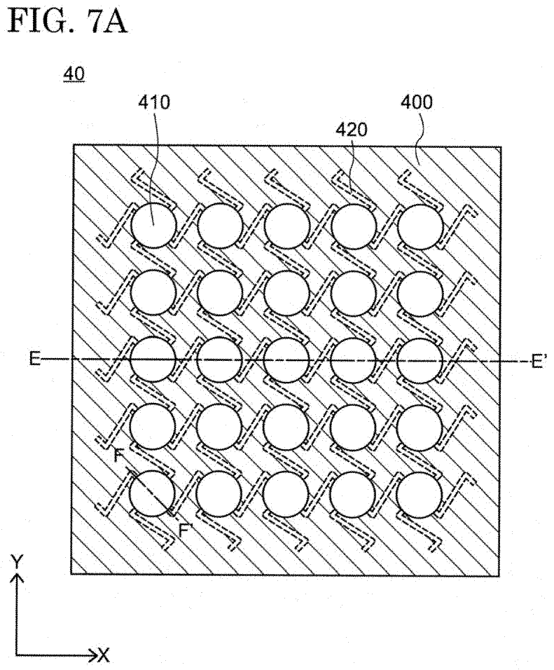

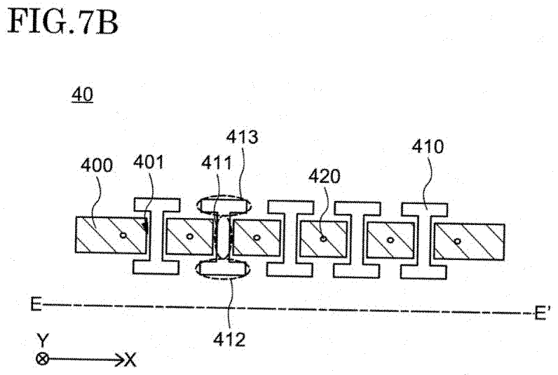

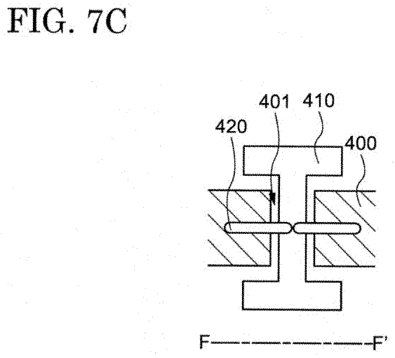

An element transfer device 40 according to an embodiment of the present invention is described with reference to FIGS. 7A to 7C. In the following description, the description of the configuration similar to that of the first to third embodiments is omitted, and the configuration different from that of the first to third embodiments is mainly described.

FIG. 7A is a schematic top view of the element transfer device 40 according to the embodiment of the present invention. Further, FIG. 7B is a schematic cross-sectional view of the element transfer device 40 according to the embodiment of the present invention. Specifically, FIG. 7B is a schematic cross-sectional view cut along the line E-E′ of FIG. 7A.

As shown in FIGS. 7A and 7B, the element transfer device 40 includes an elastic sheet 400, a pickup portion 410, and a wire 420. The elastic sheet 400 is provided with a through hole 401. The pickup portion 410 includes a shaft portion 411, a first head portion 412, and a second head portion 413. The shaft portion 411 of the pickup portion 410 is fitted in the through hole 401. Further, the wire 420 is buried in the elastic sheet 400 in a meandering manner. Further, the wire 420 is in contact with the elastic sheet 400.

FIG. 7C is a schematic enlarged cross-sectional view of the element transfer device 40 according to the embodiment of the present invention. Specifically, FIG. 7C is a schematic enlarged cross-sectional view cut along the line F-F′ of FIG. 7A.

In the through hole 401 of the elastic sheet 400, an end portion of the wire 420 is buried in the pickup portion 410. In other words, it can be said that the wire 420 connects two pickup portions 410. The wire 420 does not necessarily have to connect the adjacent pickup portions 410. Every other pickup portion 410 can be connected to the wire 420. Further, not only the adjacent pickup portions 410 in the X direction or the Y direction but also the pickup portions 410 in the X+Y direction (diagonal direction) can be connected.

In FIGS. 7A to 7C, although four wires 420 extend from one pickup portion 410, the number of wires 420 is not limited to this. Further, in FIGS. 7A to 7C, one wire 420 is provided for each connection of the pickup portions 410. However, one wire 420 can be provided so as to penetrate the pickup portion 410 and connect a plurality of pickup portions 410. Further, the end portion of the wire 420 may be fixed in the pickup portion 410.

The wire 420 may be a curved line as well as a straight line, and a straight line and a curved line can be combined.

### [Modification]

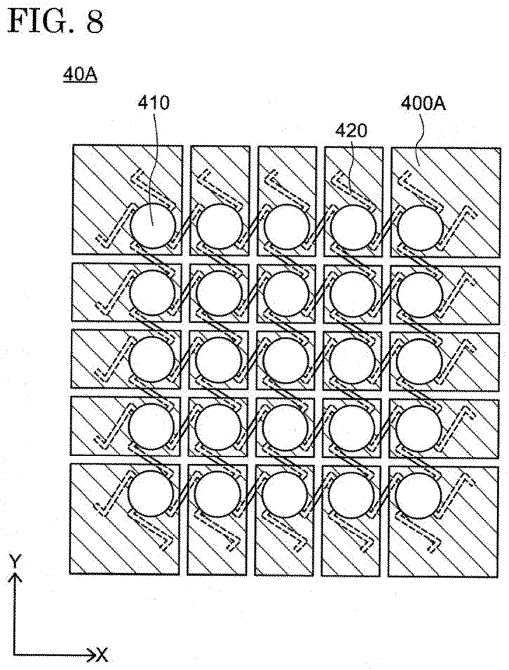

A modification of the element transfer device 40 according to the embodiment of the present invention is described with reference to FIG. 8.

FIG. 8 is a schematic top view of an element transfer device 40A according to the embodiment of the present invention. As shown in FIG. 8, the element transfer device 40A includes an elastic sheet 400A, a pickup portion 410, and a wire 420. The wire 420 is buried in the elastic sheet 400A in a meandering manner.

The elastic sheet 400A is divided at a plurality of points in the X direction and the Y direction. In FIG. 8, although the elastic sheet 400A is divided into a matrix so as to include one pickup portion 410, the elastic sheet 400A is not limited to this. One divided sheet of the elastic sheet 400A can include a plurality of pickup portions 410.

The wire 420 is exposed at the divided point of the elastic sheet 400A. Since the wire 420 is integrated with the elastic sheet 400A, each of the divided sheets of the elastic sheet 400A is connected via the wire 420. Further, since the wire 420 has rigidity, the rigidity of the element transfer device 40A can be maintained even when the elastic sheet 400A is divided.

In the element transfer device 40 or the modification thereof according to the present embodiment, the rigidity of the elastic sheet 400 can be increased by burying the wire 420 in the elastic sheet 400. Further, since the wire 420 is buried in the elastic sheet 400 in a mandering manner, the wire 420 can be extended and shrunk in accordance with the stretching and shrinking of the elastic sheet 400. Further, since the elastic sheet 400 and the wire 420 are in contact with each other and the elastic sheet 400 and the wire 420 can be integrally formed, the manufacturing cost of the element transfer device 40 can be suppressed.

### Fifth Embodiment

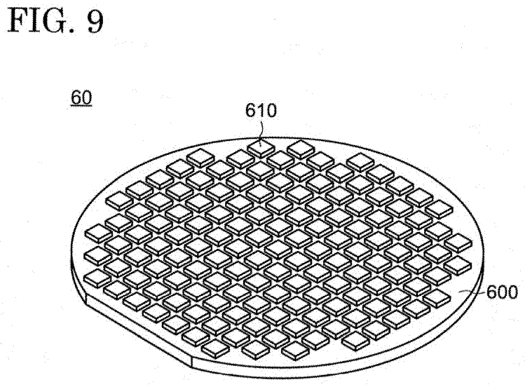

An element transfer method according to an embodiment of the present invention is described with reference to FIGS. 9 to 12. In the present embodiment, a method for transferring an element from an element substrate (first substrate) on which the element is formed to a circuit substrate (second substrate) on which a circuit for driving the element, using the element transfer device 10, is described.

### [Element Substrate (First Substrate)]

FIG. 9 is a schematic perspective view of an element substrate 60 used in the element transfer method according to the embodiment of the present invention.

As shown in FIG. 9, the element substrate 60 includes a support substrate 600 and a plurality of elements 610. In FIG. 9, although the plurality of elements 610 are arranged in a matrix on the support substrate 600, they are not limited to this arrangement. The plurality of elements 610 may be arranged in a staggered manner on the support substrate 600. In the element substrate 60, the elements 640 may be separated and arranged on the support substrate so that the element 610 can be picked up by the element transfer device 10.

A rigid substrate such as quartz, glass, silicon, or sapphire, or a flexible substrate such as polyimide, acrylic, polyethylene naphthalate (PEN), or polyethylene terephthalate (PET) can be used as the support substrate 600. Further, the support substrate 600 is not limited to a substrate, and may be a film or a sheet.

Further, the support substrate 600 may be a base material or a wafer used for forming the element 610, or may be a dicing film or a dicing sheet.

### [Circuit Substrate (Second Substrate)]

In the circuit substrate 70, a circuit for driving the element 610 is formed on a support substrate 700. A translucent substrate such as a glass substrate, a quartz substrate, a sapphire substrate, a polyimide substrate, an acrylic substrate, a siloxane substrate, or a fluororesin substrate can be used as the support substrate 700. When translucency is not required, a semiconductor substrate such as a silicon substrate, a silicon carbide substrate, or a compound semiconductor substrate, or a conductive substrate such as a stainless steel substrate can be used as the support substrate 700. Further, the support substrate 700 may be a rigid substrate having rigidity or a flexible substrate having flexibility.

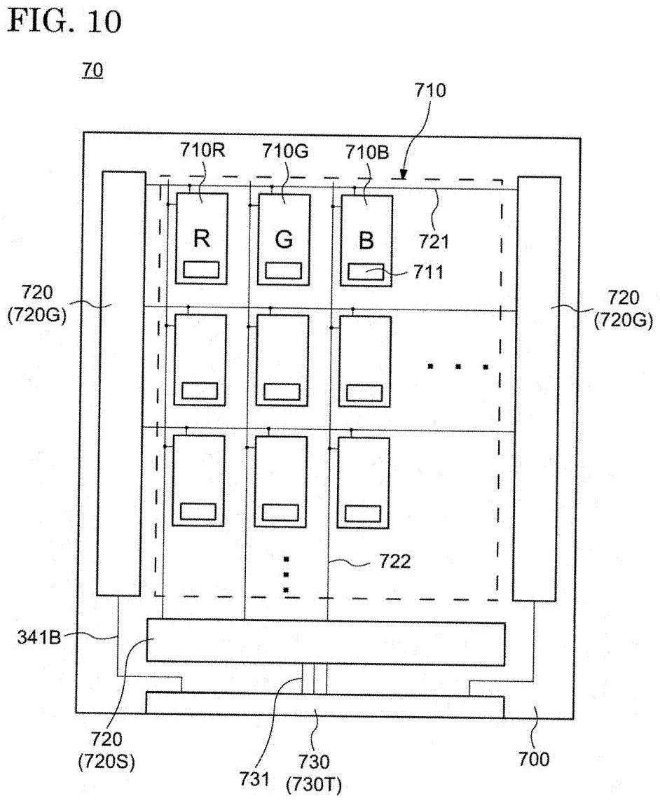

The circuit substrate 70 that can be used as a display device is described as an example of the circuit substrate 70. FIG. 10 is a block diagram showing a layout configuration of a circuit substrate 70 used in the element transfer method according to the embodiment of the present invention.

As shown in FIG. 10, a pixel region 710, a driver circuit region 720, and a terminal region 730 are provided on the substrate 700. The driver circuit region 720 and the terminal region 730 are provided around the pixel region 710.

The pixel region 710 includes a plurality of red light emitting pixels 710R, a plurality of green light emitting pixels 710G, and a plurality of blue light emitting pixels 710B which are arranged in a matrix. Although not shown in the figures, an electrode that is electrically connected to the element 610 is provided in each of the pixels. Further, in order to bond the element 610 and the electrode, a conductive adhesive 790 can be provided on the electrode. For example, the conductive adhesive 790 is an adhesive containing a conductive filler. Further, the conductive adhesive 790 may be a thermosetting adhesive or a photocurable adhesive. The conductive adhesive 790 fixes the picked-up element 610 on the support substrate 700 of the circuit substrate 70, and electrically connects the element 610 and the wiring provided on the support substrate 700. Further, the conductive adhesive 790 may be age-hardened such as a silver paste.

The driver circuit region 720 includes a gate driver circuit 720G and a source driver circuit 720S. The pixel circuit 711 and the gate driver circuit 720G are connected via a gate wiring 721. Further, the pixel circuit 711 and the source driver circuit 720S are connected via a source wiring 722. The red light emitting pixel 710R, the green light emitting pixel 710G, and the blue light emitting pixel 710B are provided at positions where the gate wiring 721 and the source wiring 722 intersect.

The terminal region 730 includes a terminal portion 730T for connecting to an external device. The terminal portion 730T and the gate driver circuit 720G are connected via a connection wiring 731. Further, the terminal portion 730T and the source driver circuit 720S are connected via a connection wiring 732. By connecting a flexible printed circuit substrate (FPC) or the like which is connected to the external device, to the terminal portion 730T, the external device and the circuit substrate 70 are connected. Each pixel circuit 711 provided on the circuit substrate 70 can be driven by a signal from the external device.

### [Transfer Method]

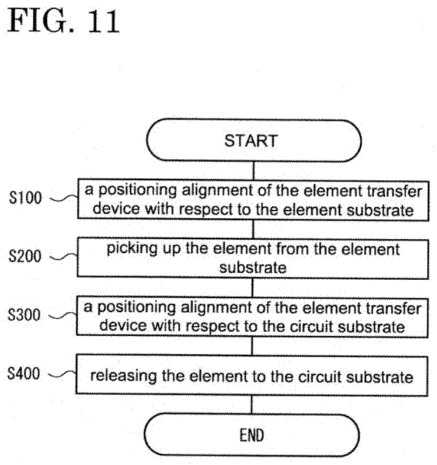

FIG. 11 is a flowchart of an element transfer method according to an embodiment of the present invention.

The element transfer method according to the present embodiment includes a step of a positioning alignment of the element transfer device 10 with respect to the first substrate 60 (S100), a step of picking up the element 610 from the first substrate 60 (S200), a step of a positioning alignment of the element transfer device with respect to the second substrate 70 (S300), and a step of releasing the element 610 to the second substrate (S400).

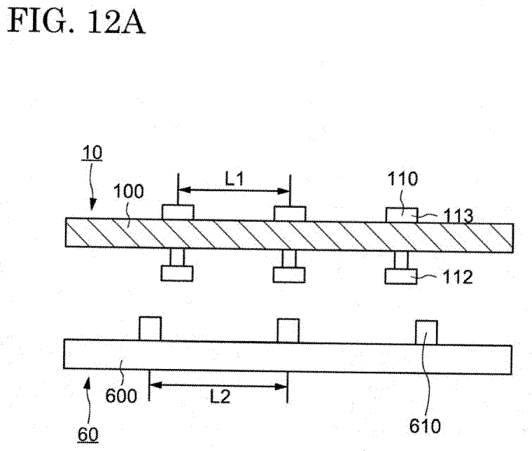

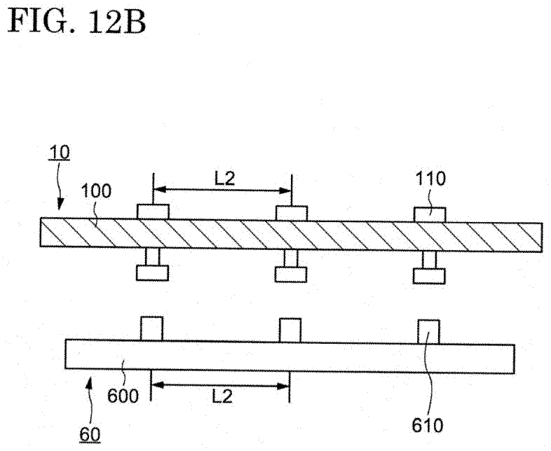

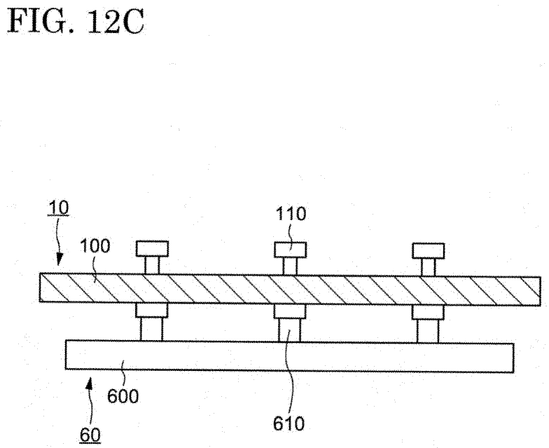

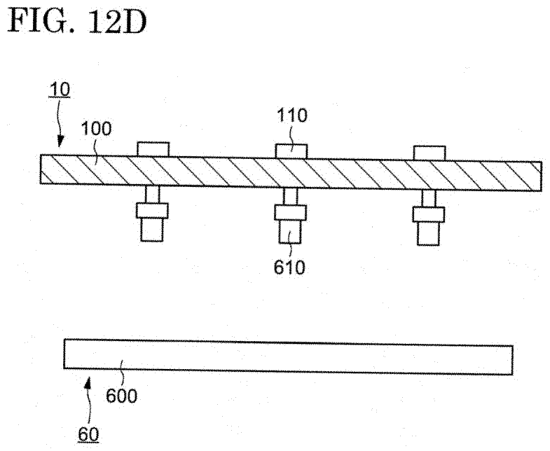

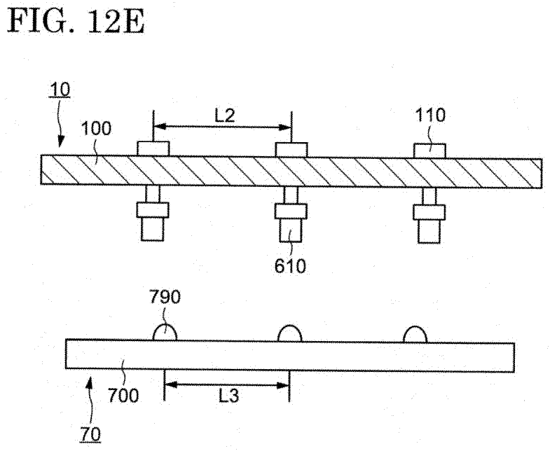

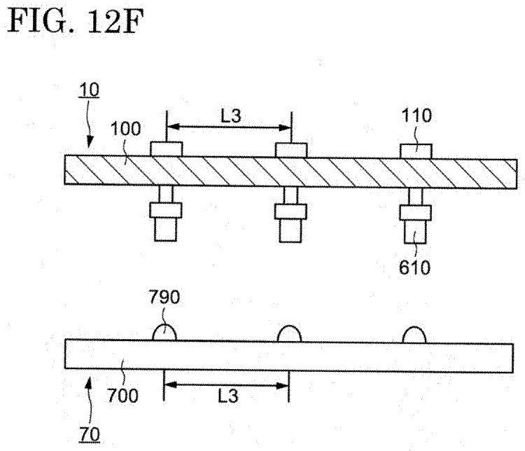

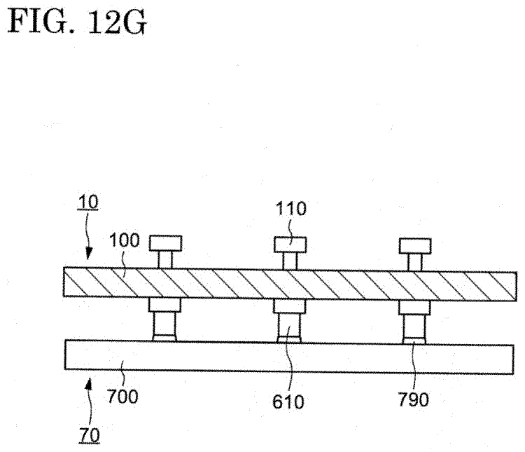

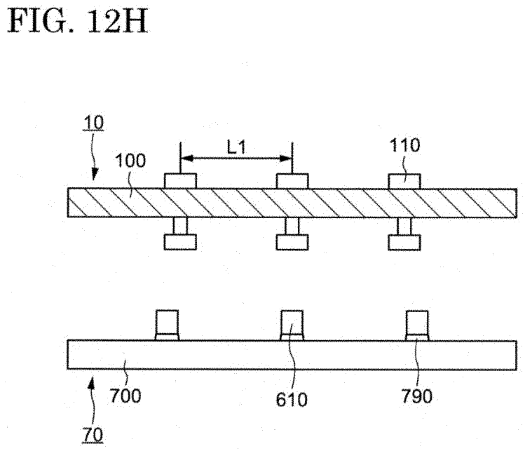

Hereinafter, the element transfer method is described in detail with reference to FIGS. 12A to 12H. Each of FIGS. 12A to 12H is a schematic cross-sectional view showing the element transfer method according to the embodiment of the present invention.

FIG. 12A shows a state in which the element transfer device 10 is placed over the element substrate 60 in the step S100. The distance between the pickup portions 110 of the element transfer device 10 is L1. Further, a pickup surface is formed on the surface of the first head portion 112 of the pickup portion 110. On the other hand, in the element substrate 60, the element 610 is adhered on the support substrate 600. The distance between the elements 610 is L2.

FIG. 12B shows a state in which the elastic sheet 100 of the element transfer device 10 is stretched in the step S100. In order to match the distance between the pickup portions 110 of the element transfer device 10 with the distance L2 between the elements 610, a force is applied to stretch and fix the elastic sheet 100. The distance between the pickup portions 110 is matched with the distance L2 between the elements 610, and the positioning alignment of the element transfer device 10 with respect to the element substrate 60 is completed.

FIG. 12C shows a state in which the pickup surface of the element transfer device 10 is pressed against the element 610 of the element substrate 60 in the step S200. In this state, a force may be applied to the elastic sheet 100 or the pickup portion 110 in order to increase the adhesive force between the pickup surface and the element 610.

FIG. 12D shows a state in which the element transfer device 10 picks up the element 610 in the step S200. When the adhesive force between the pickup portion 110 and the element 610 is larger than the adhesive force between the support substrate 600 and the element 610, the element 610 is released from the support substrate 600.

FIG. 12E shows a state in which the element transfer device 10 is placed over the circuit substrate 70 in the step S300. The distance between the pickup portions 110 of the element transfer device 10 is L2. On the other hand, the circuit substrate 70 is provided with a conductive adhesive 790 for connecting to the electrodes on the support substrate 700. The distance between the conductive adhesives 790 is L3.

FIG. 12F shows a state in which the elastic sheet 100 of the element transfer device 10 is shrunk in the step S300. In order to match the distance between the pickup portions 110 of the element transfer device 10 with the distance L3 between the conductive adhesives 790, a force is applied to shrink and fix the elastic sheet 100. The distance between the pickup portions 110 is matched with the distance L3 between the conductive adhesives 790, and the positioning alignment of the element transfer device 10 with respect to the element substrate 70 is completed.

FIG. 12G shows a state in which the element 610 adhered on the pickup surface of the element transfer device 10 is pressed against the conductive adhesive 790 of the circuit substrate 70 in the step S400. In this state, in order to increase the adhesive force between the conductive adhesive 790 and the element 610, a force may be applied to the elastic sheet 100 or the pickup portion 110.

FIG. 12H shows a state in which the element transfer device 10 releases the element 610 in the step S400. When the adhesive force between the conductive adhesive 790 and the element 610 is larger than the adhesive force between the pickup surface and the element 610, the element 610 is released from the pickup surface. When the force is removed from the elastic sheet 100 of the element transfer device 10, the distance between the pickup portions 110 returns to L1 in the steady state.

When a plurality of elements 610 are required for the circuit substrate 70, the steps S100 to S400 are repeated. For example, when the element 610 is a micro LED, the element transfer device 10 can be used to repeatedly pick up and release the red micro LED, the green micro LED, and the blue micro LED to manufacture a display device for full-color display.

Further, when the element 610 is a micro ultraviolet LED, a red phosphor, a green phosphor, and a blue phosphor are provided on the side where light is emitted from the micro ultraviolet LED to convert the emitted ultraviolet light with a phosphor so that a full-color display device can be obtained.

Each of the embodiments described above as an embodiment of the present invention can be appropriately combined and implemented as long as they do not contradict each other. Additions, deletion, or design changes of constituent elements, or additions, omissions, or changes to conditions of steps as appropriate based on the respective embodiments are also included within the scope of the present invention as long as the gist of the present invention is provided.

Other effects of the action which differ from those brought about by each of the above described embodiments, but which are apparent from the description herein or which can be readily predicted by those skilled in the art, are naturally understood to be brought about by the present invention.

What is claimed is:

1. An element transfer device comprising:
an elastic sheet comprising a through hole; and
a pickup portion comprising a shaft portion, a first head portion at a first end of the shaft portion, and a second head portion at a second end of the shaft portion,
wherein the first head portion comprises a pickup surface for adhering an element,
the shaft portion is inserted into the through hole,
the first head portion and the second head portion sandwich the elastic sheet, and
an outer diameter of the first head portion and an outer diameter of the second head portion are larger than an opening diameter of the through hole.

2. The element transfer device according to claim 1,
wherein a plurality of pairs of the through holes and the pickup portion is arranged at a predetermined distance, and
the predetermined distance is adjusted by stretching and shrinking the elastic sheet.

3. The element transfer device according to claim 1,
wherein the outer diameter of the first head portion is larger than a first opening diameter of a first opening surface of the through hole in a direction of the first head portion,
the outer diameter of the second head portion is larger than a second opening diameter of a second opening surface of the through hole in a direction of the second head portion, and
the first opening diameter is larger than the second opening diameter.

4. The element transfer device according to claim 1, wherein each of the through hole and the shaft portion comprises a taper.

5. The element transfer device according to claim 1, wherein a shape of the pickup surface is one selected from a group consisting of a circular shape, an ellipsoid shape, and a polygonal shape.

6. The element transfer device according to claim 1, wherein a cross-sectional shape of the shaft portion is one selected from a group consisting of a circular shape, an ellipsoid shape, and a polygonal shape.

7. The element transfer device according to claim 1, wherein the shaft portion is movable in the through hole.

8. The element transfer device according to claim 1, wherein a plurality of wires is provided in the elastic sheet.

9. The element transfer device according to claim 8,
wherein the plurality of wires comprises a first wire and a second wire,
the first wire extends in a first direction, and
the second wire extends in a second direction orthogonal to the first direction.

10. The element transfer device according to claim 9, wherein the first wire and the second wire are not in contact with the shaft portion.

11. The element transfer device according to claim 9,
wherein the first wire is located in a first hollow tube provided in the elastic sheet, and
the second wire is located in a second hollow tube provided in the elastic sheet.

12. The element transfer device according to claim 11, wherein the first hollow tube is not connected to the second hollow tube.

13. The element transfer device according to claim 8, wherein each of the plurality of wires is connected to the shaft portion.

14. The element transfer device according to claim 13, wherein the elastic sheet is divided into a plurality of parts.

15. The element transfer device according to claim 8, wherein the plurality of wires is in contact with the elastic sheet.

16. The element transfer device according to claim 15, wherein the elastic sheet is divided into a plurality of parts.

17. A method for transferring an element comprising the steps of:
stretching or shrinking an elastic sheet of an element transfer device so that a distance between pickup portions of the element transfer device corresponds to a distance between elements over a first substrate;
adhering the elements to pickup surfaces of the pickup portions;
releasing the elements from the first substrate;
stretching or shrinking the elastic sheet of the element transfer device so that the distance between the pickup portions of the element transfer device corresponds to a distance between electrodes over a second substrate;
placing the elements adhered to the pickup surfaces of the pickup portions on the electrodes; and
releasing the elements from the pickup surfaces of the pickup portions.
